(19) United States
(12) Patent Application Publication
(10) Pub. No.: US 2007/0236209 A1
(43) Pub. Date: Oct. 11, 2007

(54) Measuring device

(76) Inventor: Dirk Rivoir, Neulingen-Gobrichen (DE)

Correspondence Address: JACOBSON HOLMAN PLLC, 400 SEVENTH STREET N.W., SUITE 600, WASHINGTON, DC, 20004, US

(21) Appl. No.: 11/417,190

(22) Filed: May 4, 2006

(30) Foreign Application Priority Data
May 4, 2005 (DE) 10 2005 021 350.2

(51) Int. Cl. G01R 31/28

(52) U.S. Cl. 324/158.1

(57) ABSTRACT

The invention refers to a measuring device, in particular a measuring unit, as well as to a method for evaluating the position of a pointer, and furthermore to a measuring system, respectively an evaluation system, where the measuring unit is used. The measuring device serves for displaying an electric signal, for example a measuring signal. The measuring device comprises a pointer which can be positioned by an actuator depending on the signal. A position detector for the position of the pointer is suggested.

### BACKGROUND OF THE INVENTION

The invention refers to a measuring device, in particular a measuring unit for displaying an electric signal, for example of a measuring signal, comprising a pointer which can in particular be read, and which can be positioned by an actuator depending on the signal.

Measuring devices, respectively measuring units, of the kind mentioned above are used for example in commonly known measuring instruments where, for example, physical values like electricity values, a voltage, a temperature or another physical value is indicated by means of a pointer in front of a scale. The known measuring units here work analogously, that means a continuous indication of measured values is done by the measuring unit. However, also measuring units are known which carry out a digital processing of the signal, and then control the pointer, for example, via suitable stepping motors.

The use of such measuring units is very variable. For controlling and commanding of installations or vehicles measuring units mentioned above are still in use, and have not been displaced by digital displays or a display with numbers.

As a rule the measuring units are electrically impinged, that means the value to be indicated is transferred to the measuring unit in the form of an electric signal (for example voltage). Because of the electromagnetic and permanent magnetic repulsive powers an excursion of the pointer occurs on a position corresponding with the electric input signal.

The known measuring units as they are used, for example, in corresponding measuring instruments are used, in particular, for being read by a service person. However, the matter of the invention is not restricted to that. The position of the pointer in accordance with the signal can also be evaluated in another way, for example by optical scanning etc.

The known measuring units here get the pointer in a corresponding position by an actuator depending on the signal. The invention here is not restricted to a solely linear, respectively proportional, relation between the positioning of the pointer depending on the connected electric signal. Of course, also other transmitting functions can be reached for the position of the pointer because of the electric signal which must also be displayed by the actuator. The invention is not restricted here, either.

In the displays linearity deviations may occur between the entrance signal and the position of the pointer. These linearity deviations are reduced, respectively diminished, depending on the construction of the measuring unit by mechanic adjustments at the air gap or different influences of the different magnetic components. However, such an error cannot be eliminated completely. The result is that the pointer may display an incorrect value, or confuses or irritates the operator, respectively the persons reading the display of the measuring instrument, respectively the measuring unit.

An instrument as described before is known in the state of the art. Here an instrument for continuous reading the position of a movable member, in particular a display organ of measuring instruments with a central zero position is proposed which has a source of alternating-current and a mechanic part connected with the reading device and destined for inducing electric impulses. The construction of such an instrument is very complicated and requires in particular permanently a source of alternating-current in order to be able to work at all. The device known from the state of the art is furthermore characterised by an extremely complicated mechanic construction and requires a number of electrodes which collect induced impulse signals.

Furthermore a method is known from the state of the art for correcting systematic geometric errors in a turning angle measuring instrument which works such that this instrument is calibrated once, and then, because of this one-time calibration, certain correction values are determined which then are the base for indicating the value. This instrument does not work continuously and is, despite the correction factor, prone to inaccuracies in the display. In particular, deviations are not stated when, for example, the correction value changes.

### BRIEF ABSTRACT OF THE INVENTION

Coming from the state of the art it is an object of the invention to suggest how to collect the indicated value of measuring units.

In order to solve this problem a measuring device is suggested, in particular a measuring unit for displaying an electric signal, for example a measuring signal, comprising an in particular readable pointer which can be positioned by an actuator depending on the signal, which is characterised by a position detector for the position of the pointer, the position detector transferring continuously the position of the pointer to an evaluation unit which processes the signal to be displayed by the pointer.

The position detector suggested according to the invention makes it possible to recognise and evaluate continuously (of course with regard to its scale) the actually indicated position of the pointer.

This suggestion offers considerable possibilities. First of all it is possible by means of this suggestion to make sure that the pointer indicates the actual value connected to the measuring unit. For that purpose the pointer position received by the position detector is re-coupled to the input signal, the electric signal, and the correspondingly the signal is corrected. The result is a fault-free display, and the measuring unit displays exactly the value by the pointer which transfers the electric signal. Constructive conditions of the measuring unit are therefore not decisive any more in order to reach a high accuracy. The linearity problems, which cannot be eliminated anyway (for example because of friction or the arrangement of the magnetic air gap etc.) are compensated and balanced ideally by the suggestion according to the invention. However, this leads to the fact that the often high effort in precision mechanics for realising the highly accurately functioning measuring unit can be reduced without loss of precision so that the production of the measuring unit becomes more economic. This is a considerable advantage compared with the state of the art as for economic production cost a measuring unit with higher precision can be obtained!

In contrast to the solutions known from the state of the art the device of the invention works in such a way that the position detector continuously collects the actual position of the pointer, respectively the display, and transfers it also continuously to an evaluation unit which evaluates this signal accordingly. Thus, for example, errors are eliminated which may occur by calibration, or which may occur in the course of time by changes in the measuring unit, which then may not be collected by the calibration once carried out in the instruments of the state of the art. The device according to the invention always collects the actual position by means of the sensor which transfers the signal to the evaluation unit, and the evaluation unit evaluates that according to a certain algorithm so that the evaluation then leads to a corrected signal which may be used for correcting the display in such a way that permanently the displayed value also corresponds with the actual value.

The solution according to the invention is characterised, in contrast to another solution known from the state of the art, by the fact that it guarantees a very simple mechanic construction, and, nevertheless, makes a secure collecting of the position of the pointer possible, and works in particular error-free. Furthermore, the number of the reading electrodes which are required in the solutions of the state of the art, and which have to be, in particular, even arranged on different levels, can be reduced to a minimum. Furthermore it is not necessary, either, to use a method where an eliminated number of zero positions has to be counted, and then the angle position is indicated by that. This procedure also necessarily leads to mistakes which cannot be avoided in the solutions of the state of the art. In the solution according to the invention these disadvantageous effects do not occur anymore.

However, the list of advantages of the invention is not limited to this. In addition to the suggestion according to the invention to provide a position detector for the position of the pointer, even other possibilities of use are offered. Thus it is, for example, possible, to store the position indicated by the pointer.

The suggestion according to the invention thus reaches furthermore that, for example, displayed process data can be stored. Such uses can be used, for example, for the black box of high speed trains or airplanes.

A convenient development of the solution described before according to the invention is characterised by the fact that the evaluation unit is designed as signal processing unit, and this signal processing unit is able to carry out continuously a comparison between target and actual value between the signal on the input side and the pointer signal, and processes a signal on the output side under the condition that the displayed value really corresponds with the actual value of the signal. For that purpose a corresponding algorithm which will be described more detailed further on, by means of which the evaluation can be carried out without problems, is preset to the processing unit, respectively the signal processing unit.

According to the invention it is provided, corresponding to a modification of the invention, that the signal processing unit is designed in such a way that it transfers the corrected signal, respectively the signal of the output side, to the actuator.

In a preferred modification of the invention it is suggested that the measuring unit is designed analogously. An analogous measuring unit means here that the electric signal is not digitised. An analogous measuring device is characterised in particular by a continuous display range, on the other hand, a digital measuring unit is able to indicate the position of the pointer only in discrete steps. Basically the invention extends to an analogous as well as to a digital design of the measuring unit, however, the use of an analogous measuring unit, respectively the realisation of the invention in an analogous measuring unit, has substantial advantages in realisation. By means of that namely the input signal which is, as a rule, analogous does not need to be digitised in an analog-to-digital (A/D) converter. Furthermore, the suggestion according to the invention can be realised in already existing, analogously designed measuring units, for example, in moving coil instruments and the like, with only small expenses. The invention is even suited for retrofitting existing measuring units.

Preferably it is suggested that the actuator is formed by a signal power element which moves the pointer because of the signal, and a back drive element. Because of the electric signal a power moving the pointer is generated. For that purpose the signal power element serves. In order to position the pointer securely at a position corresponding with the connected signal a back drive element is provided which develops a power component which is opposite directed to the signal power element, and which positions the pointer in the desired position by equality of the forces.

In a preferred modification of the invention it is provided that the signal power element causes a movement of the pointer because of electro-magnetic and permanent-magnetic repulsive forces. Because of the magnetic effect of a current-carrying conductor it is possible to realise a repulsive force corresponding with the force of the current which serves as signal power element. It is used here that magnet poles of the same name repel each other. This makes it possible to cause a movement of the pointer. Usually the electric signal is provided as voltage which leads which leads to a corresponding current depending on the value of the signal with a resistor (assumed constantly).

The invention can be used very variably. It is suggested that the pointer carries out either a linear movement or a turning movement. Thus it is basically possible to use also the function principle of an electromagnet so that the pointer would be arranged in this case at the armature bar of the electro-magnet. Such an arrangement leads to an analogously working measuring device. Also well-known, however, are measuring units where the pointer carries out a turning movement, that means that the pointer is preferably supported on a shaft in such a way that it can rotate or turn. Of course, also other, more complicated guides are possible in order to realise a corresponding turning movement of the pointer. This is also comprised by the invention.

In a preferred modification the invention uses the fact that the measuring unit is designed, for example, according to the construction principle of a moving coil, moving iron, or rotary magnet measuring unit. As the invention, as described, is not limited to a rotating support of the pointer, the measuring unit comprises, according to the invention, a coil, iron or magnet moving together with the pointer, the coil etc. being a moving coil and so on with a rotationally supported pointer.

Cleverly a spring element is provided for the back drive element as the spring element has a linear spring constant with regard to the path of the spring, and thus causes a counter weight to the force of the signal power element. However, other back drive elements can also be used. It is, however, possible by means of the invention, to retrench the quality of the back drive element which has to be selected suitably high with the known measuring units, as the quality, that means in particular the linearity of the spring constant is not decisive anymore according to the invention. As it is, according to the invention, basically possible that by means of the determination of the position of the pointer through the position detector following up of the pointer to the actual value of the scale which corresponds with the signal, it is possible to equip the arrangement of the measuring unit according to the invention in such a way that exactly the correct value is displayed reliably without the use of very expensive measuring unit components, in particular highly linear back drive elements.

In the modification according to the invention it is suggested that the position detector comprises a sensor and a sensor element interacting with the sensor. It is a task of the position detector to transfer the position, that means the location, of the pointer. This determination of position is carried out toward a suitable reference point so that the position detector comprises preferably an element stationary at the measuring unit and an element moving together with the pointer. The use of a sensor makes it possible to transfer the respective position of the pointer, and the result is that preferably the sensor is designed stationary at the measuring unit, and the sensor elements interacting with the sensor carry out the same movements as the pointer (for example a linear or rotational movement). Basically also a reverse arrangement is possible, for example, when the sensor carries out the same movement as the pointer and the sensor elements interacting with the sensor. For example, the information given by the sensor elements differ so clearly that it is possible for the also moving sensor to identify the respective sensor elements individually, and thus to determine exactly the position of the pointer and to indicate it.

Through the selection of the sensor element and, of course, the sensor interacting with it a design of the position detector as trouble-free as possible is striven for. If, for example, the position detector is used under normal conditions it may be convenient to use it screened in the infrared spectral range in order to minimise troubling influences from the outside. A special protection housing for the sensor is here, independently from its exact design, basically convenient in order to avoid corresponding troubling effects.

The invention is not limited at all in the design of the position detector, that means the physical principles on which its way of operation is based. Thus it is suggested according to the invention that an optical, capacity, magnetic detector or one acting with electro-magnetic waves is used. Of course, an optically acting position detector is a special case of a position detector acting with electromagnetic waves.

It is, however, also possible to operate the position detector with radio frequency or micro wave. It is also possible in the frame of the invention to equip the position detector with a number of sensors which interact with a correspondingly clear point of the sensor element, and find and position it accordingly. By means of that a highly accurate determination of the position can be carried out.

Furthermore, the invention suggests that the position detector works in transmission or reflection mode. In such a modification according to the invention it is provided that the sensor comprises a light-sensitive detector. Because of the position of the sensor element, respectively the relative positioning of the sensor element to the detector, a determination of the position is possible.

By means of the suggestion according to the invention that the sensor comprises a light emitting device the invention can in a simple manner get rid off trouble signals. It is, for example, possible, that the light signal sent by the light emitting device is in a suitable way clocked, that means triggered, and the light-sensitive detector is adjusted to exactly the same cycle so that corresponding troubling signals can be filtered off as offset.

Preferably it is suggested that the sensor comprises a light emitting device as well as a light-sensitive detector, and is, for example, designed as integrated component so that the detector can be realised very small.

Preferably it is suggested that the sensor works in the infrared, optically visible or ultra-violet spectral range. This spectral range is determined in particular by LEDs as light emitting devices and diodes as optically-sensitive electrodes and can be used very conveniently.

The invention suggests several modifications how to arrange the sensor element. First of all it is possible that the sensor element is supported rotationally on the shaft, and thus carries out the same rotational movement as the pointer. This arrangement makes it possible to separate the position of the sensor element from the position of the pointer, and to realise thus the position of the pointer at another place, for example such that it is convenient for realising the measuring unit (for example mechanically protected). By means of that the length of the shaft is used conveniently.

In another clever arrangement of the measuring unit according to the invention it is provided that the sensor element is supported on a shaft rotationally by it, and a pointer carrier carrying the pointer is connected to the sensor element.

This modification gets the sensor element in direct neighbourhood to the pointer where possibly the sensor element is also part of the pointer, respectively pointer carrier or even the pointer cross.

Conveniently it is suggested that the sensor element is designed circle- or disc-like. This basically circular arrangement is selected here cleverly concentrically to the axis of the shaft in order to reach a high accuracy. A circle-like design saves mass and therefore realises the necessary turning movement, a disc-like arrangement increases the stability of the sensor element.

Preferably the sensor element is connected with the pointer. The sensor element carries out the movement of the pointer and interacts with the sensor. As by the interaction of sensor element and sensor in the position detector the respective position of the pointer has to be determined it is convenient to adapt the design of the sensor element accordingly to the movement path of the pointer. The result is that the sensor element possibly has a circular design or even a longitudinal design (with linear movements of the pointer). Conveniently the sensor element carries sensor means each of which interacts with the sensor in the desired way. Cleverly the invention is designed in such a way that at the circumference or in the edge region of the sensor element a number or even a large number of sensor means are arranged. A large number of sensor means here achieves a correspondingly high determination of the position. The sensor means are here preferably designed discrete, that means distinguishable or countable.

In a preferred modification of the invention it is provided that the sensor means are arranged incrementally at the sensor element. Cleverly the individual sensor means are arranged on the sensor element equidistant. That means they are arranged with discrete sections, the width of the increment, that means, for example their diameter of the width, being also a measurement for the accuracy of the determined position. Therefore it may be convenient to chose the diameter of a, for example, circular or disc-like, sensor element clearly larger than the length of the pointer, and thus to provided a larger number of single incrementally arranged sensor means on the sensor element. In such a modification it is then also convenient not to arrange the detector in the region of the display, respectively the pointer, but on a continuous shaft in the back region of the measuring device.

In a preferred modification of the invention it is suggested that the sensor means reflects or transmits the optical radiation received by the detector. Depending on the used radiation the sensor means thus have reflection or transmission features, and thus differ from other regions. In the simplest case, for example, a reflecting mirror design of the sensor means is used, in the other modification, for example transmitting regions, that means regions which allow beams to pass through, and non-transparent regions alternate. The result is that between the incrementally arranged sensor means regions are arranged which do not transmit radiation or reflect it.

In another modification according to the invention it is suggested that the axis of the shaft is arranged in normal position, respectively middle position, between the pointer and the sensor. Such a construction is, for example, shown in the drawing. By means of that a space-saving distribution of the elements is achieved and, nevertheless, a high accuracy of the indication of the position of the pointer remains. At the same time in this embodiment according to the invention the scale range of the measuring unit, respectively the measuring device comprising the measuring unit, does not collide with the sensor. In the normal position, respectively middle position, of the pointer it is understood here that in the usual operation of the measuring unit the given geometric conditions prevail. As the pointer is designed straight also arrangements are possible which correspond with the normal position, respectively middle position, where the longitudinal axis of the pointer, the axis of the shaft as well as the sensor are on a straight line (at least for one measured value). This is also the case in this modification according to the invention.

An example of the way a position detector functions is described in the following:

The sensor comprises a light emitting device and an optical detector. The sensor element is, for example, designed circular and has a large number of sensor means arranged incrementally and equidistant. They are reflecting in contrast to the rest of the region so that the result is that light emitting devices and detector of the sensor each can be arranged on the same side of the sensor element. When the pointer moves out of the basic position (zero position), a certain number of increments passes the sensor which generate an alternating on/off signal on the detector. The counting electronic device of the position detector counts these signals, respectively the increments, and thus determines the angle position of the pointer so that the position of the pointer is known. This is then edited accordingly.

The invention also comprises a method for evaluating the position of the pointer of a measuring unit where the pointer depicts the signal analogously, and the position of the pointer is recorded by a position detector, which is characterised by the fact that this pointer signal is transferred to an evaluation unit, and the evaluation unit edits the signal which has to be displayed by the pointer.

This method also solves the problem of the beginning. The value recorded by the position detector can be defined by this suggestion according to the invention, can be further processed accordingly in an evaluation unit and be used. The method serves for improving the accuracy of the display considerably, and to increase altogether the security of the installations equipped with a corresponding method. In contrast to the solutions known from the state of the art the position detector collects the position of the pointer continuously. In the evaluation unit this signal is also edited continuously so that a display is provided which corresponds with the actual value of the signal.

In a preferred embodiment of the invention it is suggested that the evaluation unit is designed as signal processing unit, and the signal processing unit processes the signal which has to be displayed by the pointer. This processing is carried out in multiple ways. The signal processing unit achieves that not the incoming signal, actually the input signal, is displayed but it is corrected accordingly. This correction depends here on different criteria and may follow different principles, respectively conditions.

First of all it is possible that the signal processing unit carries out a comparison between target and actual value between the signal on the input side and the pointer signal, and processes the signal on the output side (which is provided by the actuator) under the condition that the indicated value actually corresponds with the value of the signal. The aim of such a strategy is to display an accurate value by the pointer in front of its scale. Losses by friction, linearity deviations, tolerances of components and so on can be eliminated by such an embodiment of the method according to the invention, and have the effect of saving expenses accordingly in the realisation of the measuring unit according to the invention.

But this suggestion according to the invention also achieves that two measuring units can be adjusted to each other accurately in order to realise, for example, on one system a target value and on a second system an actual value, for example the speed of a train, as indicating system for the process operation with highest precision. In particular it is possible by means of the invention to realise it in already existing mechanical devices without new releasing tests or admissions for measuring units, as they are required in particular in the field of aviation and railways.

This comparison between target and actual value makes it furthermore possible to recognise malfunctions (for example too large deviations) of the measuring unit which cannot be corrected anymore, and then to give the appropriate alarm. The invention achieves a considerable increasing of the security and reliability, as it comprises eventually an auto diagnostic system of the measuring unit. This advantage exists for the method according to the invention, the measuring unit, as well as for the measuring or evaluation system which still has to be described.

Furthermore it is provided in a modification according to the invention that the signal is processed in such a way by the signal processing unit that signal values are indicated within at least one interval of signal values in another way by the pointer than the signals outside this interval.

Usually a signal is displayed by a measuring unit, for example when the pointer is supported rotationally, proportionally to its angle swing. If only, for example, a certain interval of measuring values is interesting, for example if the speed is between 0 and 300 km/h, the interval between 50 and 100 km/h, this would result with a swing range altogether (referring to 0 to 300 km/h) of, for example 180°, only in a range of 30° on the scale. The clearness just in this range of interest is small. Now it is possible by means of this modification according to the invention in the display not to assign the range of measure values of 50 to 100 km/h to 30°, but for example to 90°. The accuracy in this interval is increased as it is accordingly spread.

The display position can be adjusted via a corresponding signal processing unit in the relation to the input signal in order to generate in this way, for example, also a 100%-linear display. Also a linear display may be made to a non-linear signal.

The problem according to the invention is furthermore solved by a measuring or evaluation system for signals to be displayed which comprises a measuring unit as described, and has an evaluation unit which evaluates the pointer signals received by the position detector. This measuring system, respectively evaluation system, which uses in particular also the method described before, has, because of its design, exactly the same advantages as they have been described for the method, respectively the measuring unit, itself. The invention here is not restricted to be used only as measuring system, that means to indicate exactly correspondingly measured values (which is the actual object of a measuring unit), but comprises also individually an evaluation system in order to evaluate the displayed signals accordingly, and that means depending on the actually indicated value, because of the position of the pointer. Of course, and this is another advantage of the invention, a combination of this measuring system with the evaluation system is also part of the invention. In it all before-mentioned advantages of the invention are reached together.

It is provided cleverly that the evaluation unit is designed as storage. In this case an evaluation of this evaluation system is carried out, for example, later, namely when the storage is accordingly read and the data are processed. Furthermore the measuring or evaluation system comprises also the design where the evaluation unit is designed as signal processing unit. The modification realised in particular in a measuring system has the result that the input signal is modified by a corresponding correction in such a way that the measured value actually indicated by the pointer corresponds with the real value of the input signal. Such a modification is preferably used in a measuring system.

In this connection it is in particular pointed out that all characteristics and features with reference to the measuring unit but also methods can be transferred accordingly also with reference to the formulation of the method according to the invention and also with reference to the formulation of the measuring system, respectively evaluation system, according to the invention, and can be used according to the invention and are considered disclosed together with it. The same goes each time vice versa, which means that with reference to the method only construction characteristics, that means device characteristics, are considered and claimed also in the frame of the claims for the measuring unit, respectively the measuring and evaluation system, which belong also to the invention and disclosure. Such a connection is directly clear and understandable for an expert.

### BRIEF DESCRIPTION OF THE PREFERRED EMBODIMENT

The invention is schematically shown by means of drawings. In the figures:

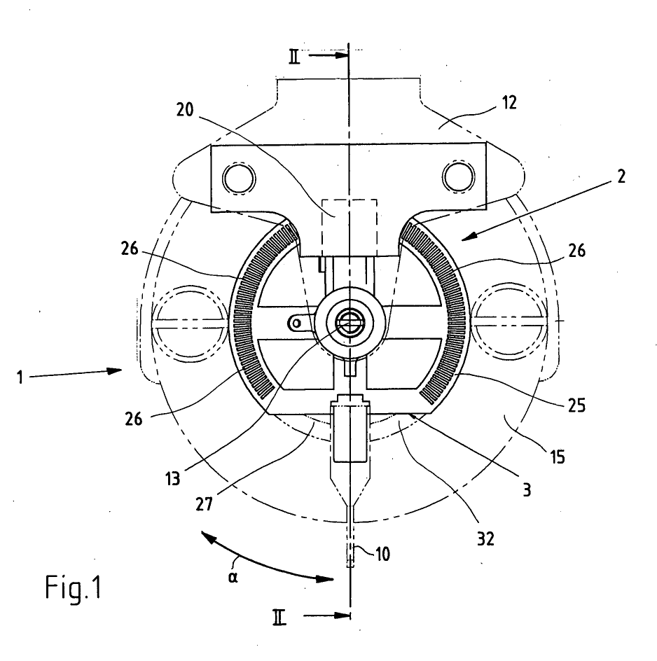

FIG. 1 the measuring unit according to the invention in a view,

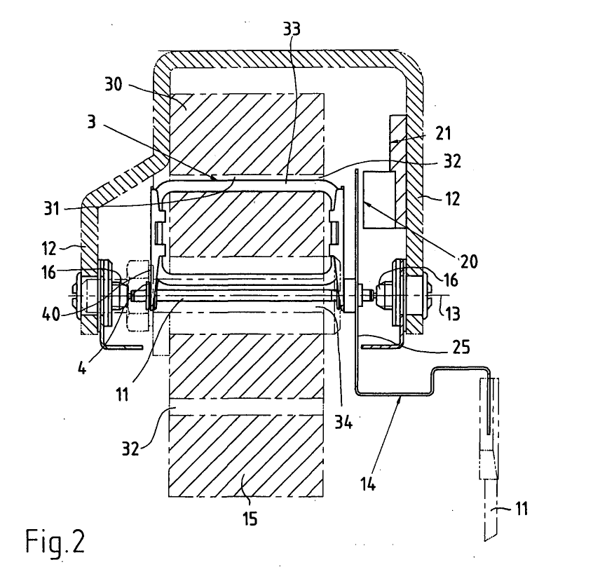

FIG. 2 a vertical section of FIG. 1 according to the line II/II,

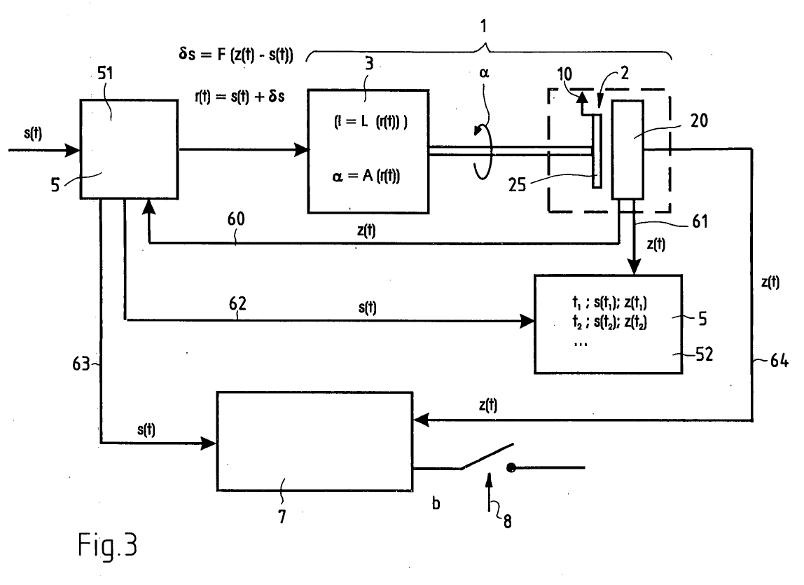

FIG. 3 the method according to the invention in a block diagram.

### DETAILED DESCRIPTION OF THE PREFERRED EMBODIMENT

The construction of the measuring unit 1 according to the invention is shown schematically in FIG. 1 and FIG. 2. The invention refers for example to a conventionally known measuring unit and adds the position detector 2 to it.

The measuring unit 1 comprises a measuring unit housing 12 which is designed, for example, like a bow, and to which may be added, for example, a cover. This depends on the respective construction conditions or the intended use. The measuring unit 1 is completed, if necessary, by a scale and a cover disc and so on to form a complete measuring instrument.

The measuring unit 1 shown in FIGS. 1, 2 is a moving coil measuring instrument, the pointer 10 is supported rotationally around the angle range a around the axis 13. The principle of the measuring unit is based on the use of the repulsion of the electro-magnetic and permanent magnetic forces. Therefore the measuring unit 1 comprises a basic body 15 which holds the permanent magnet. In the basic body 15 a circular gap 32 is provided concentrically around the axis 13. In this circular gap 32 the moving coil 31 moves which is current-carrying. The flow of the current depends, for example, on the often as voltage connected measuring signal, and results from Ohm's law. The repulsion occurs here towards the permanent magnet 30 and acts as back drive element 4 against a spring 40.

The interaction of the electro-magnetic and permanent magnetic repulsive forces leads to a signal power element, the interaction of the signal power element and the back drive element 4 results in the actuator 3.

The basic body 15 with the permanent magnet 30 is located inside the measuring unit 1, and is, at least partly, surrounded by the housing 12. The housing 12 is here arranged in such a way that it is drawn down on the left and right hand side of the basic body 15 at least up to the center of the basic body 15, and has next to the circular gap 32 also a central boring 34 through which the shaft 11 is guided. The shaft 11, on the one hand, carries the pointer 10, and, on the other hand, is supported rotationally in the accordingly easy-running pivot bearings 16 which themselves are arranged at the housing 12.

In the section according to FIG. 2 the housing 12 surrounds the top part of the basic body 15 U-like.

Above the right exterior pivot bearing 16 there is, on the inside of the housing 12, the sensor 20 which is part of the position detector 2 for determining the position, that means the position of the pointer 10.

For that purpose the sensor 20 is arranged for example on a sensor board 21 which has suitable connection contacts, for example for power supply and information transmission. Thus the housing 12 which exists anyway is used another time, namely for holding and fixing the stationary part of the position detector 2, namely the sensor 20.

As described the position detector 2 comprises the sensor 20 and the sensor element 25. The sensor element 25 here carries out in this modification of the invention exactly the same turning movement as the pointer 10. Therefore the sensor element 25 is also arranged on the shaft 11 in such a way that it cannot turn against it. The rotational movement of the actuator 3 caused by the bow-like moving coil 31 is thus transferred in an identical way to the sensor element 25.

Referring to the modification shown in FIG. 2 the pointer 10 and the sensor 20 are located on the same side of the basic body 15, that means on the same half of the shaft 11. It is, of course, possible, to arrange the basic body 15 between the sensor 20, respectively the position detector 2, and the pointer 10, that means to shift the sensor 20 to the “backside” of the measuring unit. Both solutions are part of the invention.

The sensor element 25 is designed disc- or circle-like. FIG. 1 shows that the circular sensor element 25 is not formed completely, but has a secant-like flattening 27 in its bottom region. This flattening 27 is located in that region where then, rectangularly to the plane of the sensor element 25, the pointer carrier 14 joins which then carries the pointer 10.

In the circumference region of the sensor element 25 (see FIG. 1) a number of incrementally designed, equidistant arranged sensor means 26 are provided. The sensor 20 contains in this embodiment a light emitting device as well as a detector (none is shown). The sensor means 26 is reflecting, inter-regions arranged between the respective sensor means 26 being non-reflecting. Thus during the turning movement a of the pointer 10 a sequence of light/dark impressions occur at the detector which are listed accordingly, and thus result in the position of pointer 10.

In FIG. 3 in a block diagram the procedure of the method according to the invention is shown. The measuring unit 1 is also shown schematically in this block diagram. The actuator 3 converts the signal s(t), respectively r(t), into a turning movement α. This indicated by the formula
α=A(r(t)).

As the signal s, respectively r, is a variable of the time, it is given in the functional written form s(t), respectively r(t)), as function of the time t.

As according to the invention it is also provided that instead of a turning movement of the pointer 10 also a longitudinal movement is possible, the actuator 3 carries out, in an alternative according to the invention, also a longitudinal movement, which is indicated by l=L(r(t)).

For further consideration we now refer to the turning movement α. The functionality, however, can be used in the same way in a linear or longitudinal movement l.

The measuring unit 1 converts the signal s(t) into a suitable angle position α, the position z (t) of the pointer resulting from that is determined by the position detector 2 (in interaction with the sensor element 25 with the sensor 20), and is edited in different ways.

In a first modification the pointer signal z(t) is guided via the line 60 in an evaluation unit 5 which is designed in a first modification as signal processing unit 51. In this embodiment it is striven for that the actually displayed value of the pointer 10 is exactly the value of the input signal s(t). It is therefore striven for that
s(t)=z(t).

As this is not guaranteed because of several losses (friction, linearity problems and so on) by means of the signal processing unit the input side signal s(t) is corrected by the correction signal δs, and a signal r(t) corrected in this way is transferred to the actuator 3.

The correction signal δs is therefore a function of the target/actual comparison z(t)−s(t), that means for example δs=F(z(t)−s(t)).

The function must in particular reach the aim that the target value corresponds with the actual value. The correction signal δs may here lead to an increasing or reduction of the signal of the input side, that means—depicted functionally—be positive or negative.

Besides a first modification of the method according to the invention it is, however, also possible that the pointer signal z(t) is transferred to an evaluation unit designed as storage 52. For that purpose the line 61 is provided. This storage 52 is, for example, part of a black box, and shows also the actually indicated values (also seen by the operator/driver/user). That means in this storage 52 are at least value pairs
tᵢ; z (tᵢ)
stored with i from 1 to infinite. Of course, this storage has no infinite capacity. However, the number of values to be stored is very large.

In this modification of the invention the use of a signal processing unit 51 is not necessary. The signal s (t) is given without correction to the actuator 3.

In a modification of the invention it is provided that the signal s (t) is transferred from the signal processing unit 51 via the line 62 to the storage 52, and then in the store the pointer signal z as well as the signal s are filed as function of the time.

Furthermore a control unit 7 is provided according to the invention in which the pointer signal z (t) and/or the signal s(t) to be represented are transferred. Thus the lines 63 are provided for the signal s (t), respectively the line 64 for the pointer signal z (t). The control unit then triggers, if necessary depending only on the pointer signal z, only the signal s to be represented, or only depending on an actuating signal b of an actuating unit 8 other functions. Besides these respectively isolated conditions they can, of course, be combined with one another optionally, that means depending on all three or only depending on two of the present signals b, s, z.

The control unit 7 serves, for example, for giving the alarm when the difference between the signal s and the pointer signal z exceeds threshold values. A fault of the measuring unit may be recognised for example early, before the operator who reads the measuring unit becomes irritated, and makes possibly wrong decisions because of an inaccurately displayed value of the pointer 10.

However, it is also possible, in particular by means of the service unit 8, to introduce a control function for the service staff, the service staff installing on request of an input confirmation b the control function. Then also the signal s, the pointer signal z, that means also the input confirmation signal b have to be compared and evaluated.

Of course, also the control unit 7 can be equipped with a suitable storage in order to protocol corresponding service procedures.

It is clear, that all features mentioned before, which have been described in connection with the method, if necessary are also subject of the claims of the measuring, respectively evaluation, system as the measuring system, respectively the evaluation system, refers as a matter to these functions as described in FIG. 3 and illustrated in the method.

Although the invention has been described by exact examples which are illustrated in the most extensive detail, it is pointed out that this serves only for illustration, and that the invention is not necessarily limited to it because alternative embodiments and methods become clear for experts in view of the disclosure. Accordingly changes can be considered which can be made without departing from the contents of the described invention.

1. Measuring device, in particular measuring unit for displaying an electric signal, for example of a measuring signal, comprising an in particular readable pointer which can be positioned by means of an actuator depending on the signal, characterised by a position detector (2) for the position of the pointer (10), the position detector (2) transferring continuously the position of the pointer (10) to a evaluation unit (5) which processes the signal which has to be represented by the pointer (10).

2. Measuring device according to claim 1, characterised in that the evaluation unit (5) is designed as signal processing unit (51), and the signal processing unit (51) is able to carry out continuously a comparison between target and actual value between the signal on the input side (s(t)) and the pointer signal (z(t)), and processes a signal on the output side (r(t)) under the condition that the indicated value really corresponds with the actual value of the signal.

3. Measuring device according to claim 1, characterised in that the evaluation unit (5) is designed as signal processing unit (51), and the signal processing unit is able to carry out continuously a comparison between target and actual value between the signal (s(t)) on the input side and the pointer signal (z(t)) and processes a signal (r(t)) on the output side under the condition that the indicated value corresponds really with the actual value of the signal, and the signal processing unit (51) is designed in such a way that it passes the corrected signal, respectively the signal on the output side (r(t)), to the actuator (3).

4. Measuring device according to claim 1, characterised in that the position detector (2) comprises a sensor (20) and a sensor element (25) interacting with the sensor (20), and/or is designed as optical, capacity, magnetic or with magnetic waves acting position detector (2), and/or the position detector (2) works in transmission or reflection manner.

5. Measuring device according to claim 1, characterised in that the position detector (2) comprises a sensor (20) and a sensor element (25) interacting with the sensor (20), and the sensor (20) is designed stationary at the measuring device (1), and the sensor element is designed moving together with the pointer (10), and/or the position detector (2) comprises a sensor (20) and a sensor element (25) interacting with the sensor (20), and the sensor (20) comprises at least one light-sensitive detector.

6. Measuring device according to claim 1, characterised in that the position detector (2) comprises a sensor (20) and a sensor element (25) interacting with the sensor (20), and the sensor (20) comprises a light-emitting device.

7. Measuring device according to claim 1, characterized in that the position detector (2) comprises a sensor (20) and a sensor element (25) interacting with the sensor (20), and the sensor (20) works in the in infra-red, optically visible or ultra-violet spectral range, and/or the sensor element (25) is supported rotationally on the shaft (11) and thus carries out the same rotationally movement as the pointer (10).

8. Measuring device according to claim 1, characterized in that the position detector (2) comprises a sensor (20) and a sensor element (25) interacting with the sensor (20), and the sensor element (25) is supported rotationally on a shaft (11), and at the sensor element (25) a pointer carrier (14) joins which carries the pointer (10), and/or the sensor element (25) is designed like a circle or a disc, and/or the position detector (2) comprises a sensor (20) and a sensor element (25) interacting with the sensor (20), and a number of sensor means (26) is arranged at the circumference or the edge region of the sensor element (25).

9. Measuring device according to claim 1, characterized in that the position detector (2) comprises a sensor (20) and a sensor element (25) interacting with the sensor (20), and a number of sensor means (26) is arranged at the circumference or the edge region of the sensor element (25), and the sensor means (26) are arranged incrementally at the sensor element (25), and/or the sensor means (26) reflects or transmits the optical radiation absorbed by the detector.

10. Measuring device according to claim 1, characterised in that the position detector (2) comprises a sensor (20) and a sensor element (25) interacting with the sensor (20), and on the circumference or the edge region of the sensor element (25) a number of sensor means (26) is arranged, and the sensor means (26) are arranged incrementally at the sensor element (25), and/or the sensor element (26) reflects or transmits the optical radiation absorbed by the detector, and between the incrementally arranged sensor means (26) regions are arranged which do not transmit neither reflect the radiation.

11. Measuring device according to claim 1, characterised in that a measuring unit housing (12) is provided which carries the sensor (20), and/or the position detector (2) comprises a sensor (20) and a sensor element (25) interacting with the sensor (20), and the sensor (20) is arranged on a sensor board (21) with connection contacts, and/or the axis (13) of the shaft is arranged in normal or middle position of the pointer (10) between the pointer (10) and the sensor (20).

12. Measuring device according to claim 1, characterised in that the measuring device (1) is designed analogously.

13. Measuring device according to claim 1, characterised by a linear movement or turning movement (a) of the pointer (10).

14. Method for plotting the position of the pointer of a measuring device, in particular a measuring unit, the pointer representing the signal analogously, and the position of the pointer being recorded by a position detector, characterised in that this pointer signal is transferred to an evaluation unit, and the evaluation unit processes the signal to be displayed by the pointer.

15. Method according to claim 14, characterised in that the evaluation unit is designed as signal processing unit, and the signal processing unit carries out a comparison between target and actual value between the signal on the input side and the pointer signal, and processes the signal on the output side under the condition that the shown value corresponds actually with the value of the signal.

16. Method according to claim 14, characterised in that the evaluation unit serves as storage, in particular for storing the pointer signals as function of the time, and/or the evaluation unit serves as storage, in particular for storing the pointer signals as function of the time, and the storage also stores the signal as function of the time.

17. Method according to claim 14, characterized in that the signal is processed by the signal processing unit in such a way that the signal values within at least one interval of signal values are displayed by the pointer in another way than the signal values outside this interval.

18. Method according to claim 14, characterised in that a control unit is provided to which the pointer signal and/or the signal which has to be displayed is transferred, and the control unit triggers other functions, depending on the pointer signal and/or the signal which has to be displayed and/or an actuating signal of an actuating unit.

19. Measuring and/or evaluation system for signals to be displayed, with a measuring device, in particular a measuring unit for representing an electric signal, for example a measuring signal, comprising an in particular readable pointer which can be positioned by an actuator depending on the signal, with a position detector (2) for the position of the pointer (10), the position detector (2) transferring the position of the pointer (10) continuously to an evaluation unit (5) which processes the signal to be displayed by the pointer (10).

20. Measuring and/or evaluation system according to claim 19, characterised in that the evaluation unit (5) is designed as storage (52), and/or the evaluation unit (5) is designed as signal processing unit (51).
